(19) United States
(12) Patent Application Publication
(10) Pub. No.: US 2015/0178162 A1
(43) Pub. Date: Jun. 25, 2015

(54) Method for Recovering Recordings in a Storage Device and System for Implementing Same

(71) Applicant: "RAIDIX" LLC, St. Petersburg (RU)

(72) Inventors: Alexey V. MAROV, Vologda (RU); Alexey Y. UTESHEV, St. Petersburg (RU)

(21) Appl. No.: 14/643,238

(22) Filed: Mar. 10, 2015

Related U.S. Application Data
(63) Continuation of application No. PCT/RU2013/000579, filed on Jul. 9, 2013.

(30) Foreign Application Priority Data
Sep. 12, 2012 (RU) 2012140679

(51) Int. Cl. G06F 11/10; H03M 13/15

(52) U.S. Cl. CPC G06F 11/1096; G06F 11/1004; H03M 13/152; G06F 11/1068

(57) ABSTRACT

The memory of the storage device is divided into information areas of identical size selected from different parts of the storage device, and control zones are selected from different parts of the device. Each group of data is a set of code words written to a corresponding information zone. Three reference control sums S₀, S₁, S₂, each according to a corresponding preset formula, are established by a computation unit. The reference control sums are written as a code word with the same number to a corresponding control zone. If a part of the storage device fails and data becomes corrupted, the current control sums are calculated with the aid of the computation unit. The values of the stored reference control sums and the current control sums are used for recovering lost data. The number of equations depends on the number of failed or faulty zones in the storage device.

### RELATED APPLICATIONS

This application is a Continuation application of International Application PCT/RU2013/000579, filed on Jul. 9, 2013, which in turn claims priority to Russian Patent Applications No. RU2012140679, filed Sep. 12, 2012, both of which are incorporated herein by reference in their entirety.

### FIELD OF THE INVENTION

The present invention relates to the systems for detecting and correcting data errors on data carriers, in particular in the case of failure or damage of a part of a storage device or corruption of data on the storage device.

### BACKGROUND OF THE INVENTION

A key technology to ensure reliability of storing data in the storage device is the ability to recover the data in case of failure of one or more zones of the storage device. At present, most storage devices are used to store large amounts of information, represented as disks arrays, one may consider the possibility of data recovery in case of failure of one or more hard disks. For this, a variety of erasure coding methods and so-called redundant disks arrays RAID (redundant array of independent disks) are used. The recovery is performed by calculating and storing the redundant information (checksums), which allows the recovery of the lost data, but requires additional disk space. (See, for example, Anvin, NR (last update 20 Dec. 2011). Obtained in Aug. 25, 2012 at the address http://ftp.kernel.org/pub/linux/kernel/people/ripa/raid6.pdf).

The methods and systems used to recover records in storage devices using RAID arrays are described in many patent documents, as an example, U.S. Pat. No. 7,392,458 (publ. 24 Jun. 2008), U.S. Pat. No. 7,437,658 (publ. 14 Oct. 2008), U.S. Pat. No. 7,600,176 (publ. 6 Oct. 2009); in applications for U.S. Patent No. 2009/0132851 (publ. 21 May 2009), 20100229033, (publ. 9 Sep. 2010), 20110145677 (publ. 16 Jun. 2011), 20110167294 (publ. 7 Jul. 2011), 20110264949 (publ. 27 Oct. 2011).

The closest solution to the present is according to RF patent No. 2448361, published on 24 Apr. 2012. This solution suggests a method to restore records in a storage device, wherein when data is written into information zones of the storage device, two reference checksums, calculated by the predetermined formula, are entered in its respective control zones, and in the process of using the storage device, the current checksums are repeatedly calculated by the computing unit by the same formula for each set of code words with the same numbers in all information areas and the obtained current checksum is compared with the corresponding reference checksum to define the syndrome of errors and to replace the identified write errors with the correct values. The technical result of the invention under the patent RU 2448361 is the increased speed of calculations in the recovery disk.

However, the known methods may not ensure sufficient reliability for large arrays of stored information due to the parameters of reliability of modern storage devices. Thus, the current level of technology enables to ensure the sufficient reliability for arrays up to 24 TB, combined with RAID-6 technology. When using a large number of disks, the real risk of failure of two or more disks may appear. In practice, this risk is overcome by splitting up large arrays into the small, which implies additional expenses to use large amounts of memory to store the checksums. Thus, there is a need for new methods of records recovery to store large amounts of data in a storage device.

### SUMMARY OF THE INVENTION

The present invention provides for the calculation and storage of three checksums in a memory. This allows restoration of a greater number of simultaneously failed parts of a storage device, which increases its performance and reliability, while reducing the amount of memory needed to store a checksum in large arrays. Moreover, the proposed method allows not only to recover data in case of failure or damage of the storage device, but also provides data recovery in case of data corruption of the storage device.

To solve the problem and to achieve the said technical result, the present invention provides a method to recover records in the storage device in case of failure or damage of a part of the storage device or data corruption of the storage device.

To implement this method, the said memory of the storage device is divided into information and control zones of equal size, selected from different parts of the storage device.

Each group of data to be saved is written in the form of a set of code words into a corresponding information zone. Each time the saved record is defined in a storage device by using the corresponding computing unit with three reference checksums S₀, S₁, S₂, each corresponds to a predetermined formula:

$${S}_{0} = {\sum }_{i = 0}^{n - 1} {D}_{i} = {D}_{0} + {D}_{1} + … + {D}_{n - 1}$$

$$\begin{matrix}{S}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

$$\begin{matrix}{S}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} = \\ = ( ( ( {D}_{0} {a}^{2} + {D}_{1} ) {a}^{2} + {D}_{2} ) {a}^{2} + … + {D}_{n - 1} )\end{matrix}$$

Where Dᵢ−i-information area in which the code words are recorded

d_{i,1}, d_{i,2}, . . . , d_{i,s-1}; i=0, . . . , n−1, the code words are elements of the Galois field;

n is the number of information zones;

s is the number of code words in one information zone;

a is a primitive element of the Galois field.

Next, each found reference checksum is written in the form of code words with the same number in the corresponding control zone, each of three checksums is stored in a separate zone of the storage device. In case of the failure or damage of a part of the storage device, wherein the corrupted data is detected, the current checksums are calculated with the aid of the computing unit by formulas for each set of code words with the same numbers in all of the information zones.

The values of the stored reference checksums and the current checksums are used to restore the lost data, wherein the lost data is recovered with the reference and current checksums by solving the systems of equations obtained from the formulas of checksums calculation. The number of equations in the system depends on the number of failed or damaged zones of the storage device.

This method allows to circumvent the technical limitations of storage element reliability and to create larger arrays of records in the storage device. This method restores data when up to three simultaneous failures arise. Failures can also occur in the part of the storage device that stores the checksums. Furthermore, this method allows to recover both read and write errors, which are not registered by the hardware. These results can be achieved by all features of this method, including the formation of three checksums stored in different parts of the storage device. It is important that the control checksums are calculated using the three formulas presented above and that the data is restored by using the reference and the current checksums and solving the systems of equations obtained from the formulas of checksums calculating.

The records recovery system of the storage device in case of failure or damage of a part of the storage device or data corruption is based on the method, which contains:
a memory device, which includes n equal size zones of information selected from different parts of the storage device and three control zones, selected from different parts of the storage device;
a computing unit.

Each n information zone of the storage device is performed with the ability to write the group of data as a set of code words in itself; each of the said three control zones of the storage device is performed with the ability to write the corresponding checksum in itself;

the said computing unit is configured to:

define the reference checksums by using a predetermined formula, for each set of code words, where i=0, . . . , n−1 in all the said n information zones with every record of the data to be stored in the said storage device.

The following formulas are used to calculate the S₀, S₁, S₂ checksums:

$${S}_{0} = {\sum }_{i = 0}^{n - 1} {D}_{i} = {D}_{0} + {D}_{1} + … + {D}_{n - 1}$$

$$\begin{matrix}{S}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

$$\begin{matrix}{S}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} = \\ = ( ( ( {D}_{0} {a}^{2} + {D}_{1} ) {a}^{2} + {D}_{2} ) {a}^{2} + … + {D}_{n - 1} )\end{matrix}$$

where Dᵢ denotes the i-th information area in which the code words d_{i,1}, d_{i,2}, . . . , d_{i,s-1} are recorded; i=0, . . . , n−1, the code words are treated as the elements of the Galois field;

n is the number of information areas;

s is the number of code words in one information area;

a is a primitive element of the Galois field.

The computing unit is designed with the ability to define the current checksums by the said formulas for each set of code words with the same numbers in all information zones in case of failure or damage of a part of memory of the storage device, the values of the stored reference checksums are used to recover the lost data. The lost data can be recovered using the reference and the current checksums by solving a system of equations obtained by the formula for checksums calculating, the number of equations in the system depends on the number of failed or damaged zones of the storage device.

As in the case of this method, the system creates larger storage arrays, to recover up to three simultaneously failed parts of the storage devices and to restore the corrupted data, which is not registered by the hardware.

In the particular case of the realization of this method, the values of the stored reference checksums and the current checksums are additionally used to detect the corrupted data. It is necessary to determine the location of the corrupted data. However, to restore the lost data, the presence of the corrupted data is determined by comparing the reference and the current checksums and a location of the corrupted data is defined using the system of equations obtained by the formulas of checksums calculating.

An application of the operations of this method, including the design of the system extends the scope of the invention to search for corrupted data in the array.

Another feature of the method, as well as of the system of the present invention is that the computing unit is a part of the said storage device. In another embodiment, the computing unit is external according to the said storage device.

### BRIEF DESCRIPTION OF THE DRAWINGS

The following detailed description is illustrated with drawings.

FIG. 1 illustrates splitting a disk into the blocks that comprise the stripe.

FIG. 2 illustrates splitting the information zones and code zones into the areas to store the code words.

### DETAILED DESCRIPTION OF THE PREFERRED EMBODIMENTS

The claimed method is implemented as follows. The storage device is characterized by the common amount of memory. To implement this method, the total amount of memory should be split into information zones of the same size, selected from different parts of the storage device, and control zones, selected from different parts of the storage device.

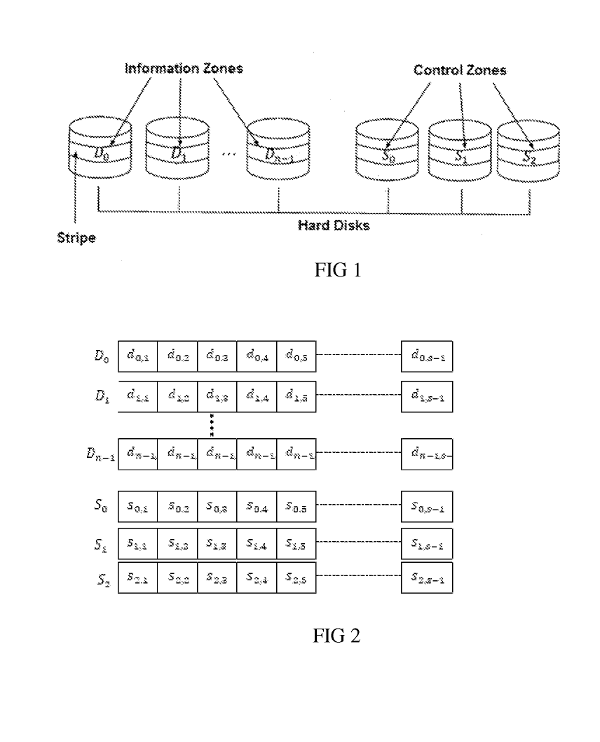

When a hard disk array is used as a storage device, disks are split into blocks of equal length. The sequence of blocks with the same numbers is located on different disks forms a stripe (FIG. 1). The information zones and the control zones are the blocks of one stripe stored on different disks. Splitting the information zones and the code zones into the areas to store the code words is illustrated in FIG. 2.

The following detailed description is based on the illustrative example, which demonstrates that the storage device is an array built from the multiple hard drives. The present invention can be also applied to storage devices of different types, for example, to a flash-memory based storage devices.

The data to be stored is divided into the blocks wherein length is equal to the length of the hard disk's block. This data is written into the blocks of one stripe on different disks. For these blocks of the stripe, the following formulas are used:

$${S}_{0} = {\sum }_{i = 0}^{n - 1} {D}_{i} = {D}_{0} + {D}_{1} + … + {D}_{n - 1}$$

$$\begin{matrix}{S}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

$$\begin{matrix}{S}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} = \\ = ( ( ( {D}_{0} {a}^{2} + {D}_{1} ) {a}^{2} + {D}_{2} ) {a}^{2} + … + {D}_{n - 1} )\end{matrix}$$

where Dᵢ denotes the i-th information area in which the code words d_{i,1}, d_{i,2}, . . . , d_{i,s-1} are recorded; i=0, . . . , n−1, the code words are treated as the elements of the Galois field;

n is the number of information areas;

s is the number of code words in one information area;

a is a primitive element of the Galois field.

The computing unit calculates the S₀, S₁, S₂ syndrome values. A multiplication of the Dᵢ by a primitive element a of a field or its power is considered as multiplication of corresponding polynomials modulo an irreducible polynomial generating the field. An operation of addition is considered as the operation of bitwise summation modulo 2 (XOR).

For the aim of computation optimization, in practical implementation, the checksum calculation is performed according to the Homer scheme:

S₀=D₀+D₁+ . . . +Dₙ₋₁

S₁=(((D₀a+D₁)a+D₂)a+ . . . +Dₙ₋₁)

S₂=(((D₀a²+D₁)a²+D₂)a²+ . . . +Dₙ₋₁)

The calculated values for syndromes are recorded on the disks to the same stripe as the data blocks.

If the damage or failure of a part of the storage device or data corruption occurs, the data recovery is performed by solving the system of equations, obtained from the formulas of checksums calculation. The choice for the coefficients of equations the certain powers aⁱ of the primitive element guarantees the solvability of the system of equations with respect to any three of the values D₀, D₁, . . . , Dₙ₋₁.

Consider the situation when storage device or its part is damaged during operation process. For an array of hard disks, it means that corruption occurs in the blocks of the stripe stored on the disks. The lost data is then recovered by stripes.

Consider first the case, when one block of the stripe is damaged, that means a single disk array is failed. If the failed block is located within the control area, then the computing unit, using the formulas for checksum calculation, recalculates the current value for the corresponding damaged checksum. The obtained value is written instead of the invalid.

In case where the damaged block happens to be within the information zone and the place j of this block is detected with hardware, the true value for D is restored with the aid of recalculation of the current value for the first checksum with omitting the summand corresponding to the failed block:

$${\tilde{S}}_{0} = {\sum }_{{i = 0}_{i \neq j}}^{n - 1} {D}_{i} = {D}_{0} + {D}_{1} + … + {D}_{j - 1} + {D}_{j + 1} + … + {D}_{n - 1}$$

Using the value of the stored reference checksum S₀ and the value of the current checksum \tilde{S}₀, the computing unit calculates the value of the failed information zone by the formula Dⱼ=S₀+\tilde{S}₀. The obtained value is then written instead of the invalid.

In case of damage to one information zone, the data can also be restored with the aid of checksum S₁. In comparison with the algorithm mentioned above, this method requires more computational resources, but necessity in its usage is justified in the situation where, in addition to the damage occurrence of the information block, the S₀ checksum block is also damaged in the stripe. Moreover, this recovery method can be applied in advanced reconstruction mode. The advanced reconstruction mode is a reading data mode, which speeds up the process of obtaining information, when the read speed of any drive falls. The system can restore the data from a slow disk instead of performing the reading operation. For example, if in the process of reading blocks from a disk, the checksum S₀, S₂ and one information zone are remained as unread, it is possible, without waiting for the reading process completing, to restore the value of the information zone, and to recalculate the values S₀, S₂ of checksums. The advanced reconstruction mode can speed up the reading process, if any drive has started to work slowly.

For recovering the damaged block Dⱼ with the aid of the checksum S₁, its current value \tilde{S}₁ is recalculated by using the computing unit by the formula:

$$\begin{matrix}{\tilde{S}}_{1} = {\sum }_{{i = 0}_{i \neq j}}^{n - 1} {D}_{i} {a}^{n - i - 1} \\ = {D}_{0} {a}^{n - 1} + {D}_{1} {a}^{n - 2} + … + {D}_{j - 1} {a}^{n - j} + {D}_{j + 1} {a}^{n - j - 2} … + {D}_{n - 1}\end{matrix}$$

(thus, the value of the failed block is ignored in calculation of the checksum).

Using the value of the stored reference checksum S₁ and the value of the current checksum \tilde{S}₁, the computing unit calculates the value of the failed information zone according to the formula:

Dⱼ=(S₁+\tilde{S}₁)a^{-(n-j-1)}

Here a⁻¹ means inversion of the element of the Galois field.

The obtained value is written instead of the invalid.

Calculating the inverse element of the field requires substantial computing resources.

In practice, it is better to choose the values of the inverse elements from the pre-calculated tables.

In case of damage to one information zone, data can be restored at the expense checksum S₂. This method requires more computational resources, but it is necessary, if in addition to the damage of the information zone, the S₀ checksum block in the stripe is also damaged. Moreover, this recovery method can be applied in advanced reconstruction mode. If a block Dⱼ of the information zone is damaged, where j is the number of the damaged unit in stripe, it is known to us, because the failure is logged by the hardware. Then, the computing unit calculates the current checksum \tilde{S}₂. Then, the current checksum \tilde{S}₂ is calculated by using the computing unit. Wherein the value of the failed block stripe is passed when the current checksum is calculated.

The computing unit according to the formula calculates the value of the current checksum:

$$\begin{matrix}{\tilde{S}}_{2} = {\sum }_{{i = 0}_{i \neq j}}^{n - 1} {D}_{i} {a}^{2 ( n - i - 1 )} \\ = {D}_{0} {a}^{2 ( n - 1 )} + … + {D}_{j - 1} {a}^{2 ( n - j )} + {D}_{j + 1} {a}^{2 ( n - j - 2 )} + … + {D}_{n - 1}\end{matrix}$$

Using the value of the stored reference checksum S₂ and the value of the current checksum \tilde{S}₂, the computing unit calculates the value of the invalid information zone according to the formula Dⱼ=(S₂+\tilde{S}₂)a^{-2(n-j-1)}

The obtained value is written instead of the invalid.

Consider now the case where two blocks are damaged in the stripe, which corresponds to the failure of two disks in the array. In addition, this recovery method is applied, if unrecoverable reading error occurs (UER) during the reconstruction of one of the failed disk, and, therefore, two blocks are damaged. If the blocks of the control zones are damaged, then the computing unit calculates the current checksum that corresponds to the damaged control zones using the checksum calculation formulas. The obtained checksum values are recorded instead of the damaged values. If one of the damaged blocks belongs to the information zone and the other one belongs to the control zone, the data is restored according to the scheme described above for one of the failed blocks, and the value of the damaged control zone is calculated according to the formula of checksums calculating.

Let Dⱼ and Dₖ blocks of the information zone be damaged, with their numbers j and k be discovered by the hardware. Then, the computing unit recalculates the current checksums \tilde{S}₀, \tilde{S}₁ with omitting the summands corresponding to the failed blocks:

$$\begin{matrix}{\tilde{S}}_{0} = {\sum }_{{i = 0}_{i \neq j , i \neq k}}^{n - 1} {D}_{i} \\ = {D}_{0} + {D}_{1} + … + {D}_{j - 1} + {D}_{j + 1} + … + {D}_{k - 1} + {D}_{k + 1} + … + {D}_{n - 1}\end{matrix}$$

$$\begin{matrix}{\tilde{S}}_{1} = {\sum }_{{i = 0}_{i \neq j , i \neq k}}^{n - 1} {D}_{i} {a}^{n - i - 1} \\ = {D}_{0} {a}^{n - 1} + … + {D}_{j - 1} {a}^{n - j} + {D}_{j + 1} {a}^{n - j - 2} + … + \\ {D}_{k - 1} {a}^{n - k} + {D}_{k + 1} {a}^{n - k - 2} + … + {D}_{n - 1}\end{matrix}$$

Using the values of the stored reference checksums S₀, S₁ and the current checksums \tilde{S}₀, \tilde{S}₁, the computing unit calculates the values of the invalid information zones according to the formulas:

Dₖ=(S₁+\tilde{S}₁+(S₀+\tilde{S}₀)a^{n-j-1})[a^{n-k-1}+a^{n-j-1}]⁻¹

Dⱼ=S₀+\tilde{S}₀+Dₖ

The obtained values are recorded instead of the invalid.

This recovery method can also be applied in the advanced reconstruction mode.

In case of damage of two information zones, the data can also be restored with the aid of checksums S₀, S₂. In comparison with the previous approach, this method requires more computational resources. However, its necessity is caused by the situation where, in addition to the damage of the information zone, the checksum block S₁ in the stripe is also damaged.

Moreover, this recovery method can be applied in the mode of advanced reconstruction. If the damaged blocks are denoted by Dⱼ and Dₖ, one should recalculate the checksums \tilde{S}₀, \tilde{S}₂ by the formulas:

$$\begin{matrix}{\tilde{S}}_{0} = {\sum }_{{i = 0}_{i \neq j , i \neq k}}^{n - 1} {D}_{i} \\ = {D}_{0} + {D}_{1} + … + {D}_{j - 1} + {D}_{j + 1} + … + {D}_{k - 1} + {D}_{k + 1} + … + {D}_{n - 1}\end{matrix}$$

$$\begin{matrix}{\tilde{S}}_{2} = {\sum }_{{i = 0}_{i \neq j , i \neq k}}^{n - 1} {D}_{i} {a}^{2 ( n - i - 1 )} \\ = {D}_{0} {a}^{2 ( n - 1 )} + … + {D}_{j - 1} {a}^{2 ( n - j )} + {D}_{j + 1} {a}^{2 ( n - j - 2 )} + … + {D}_{k - 1} {a}^{2 ( n - k )} + \\ {D}_{k + 1} {a}^{2 ( n - k - 2 )} + … + {D}_{n - 1}\end{matrix}$$

Using the values of the stored reference checksums S₀, S₂ and the values of the current checksums \tilde{S}₀, \tilde{S}₂, the computing unit calculates the values of the damaged information zones according to the formulas:

Dₖ=(S₂+\tilde{S}₂+(S₀+\tilde{S}₀)a^{2(n-j-1)})[a^{2(n-k-1)}+a^{2(n-j-1)}]⁻¹

Dⱼ=S₀+\tilde{S}₀+Dₖ

The obtained values are recorded instead of the invalid.

In case of damage of two information zones, the data can also be restored with the aid of checksums S₁, S₂. In comparison with the previous approach, this method requires more computational resources. However, its necessity is caused by the situation where, in addition to the damage of the information zone, the checksum block S₀ in the stripe is also damaged. Moreover, this recovery method can be applied in the mode of advanced reconstruction. If the damaged blocks are denoted by Dⱼ and Dₖ, one should recalculate the checksums \tilde{S}₁, \tilde{S}₂ by the formulas:

$$\begin{matrix}{\tilde{S}}_{1} = {\sum }_{{i = 0}_{i \neq j , i \neq k}}^{n - 1} {D}_{i} {a}^{n - i - 1} \\ = {D}_{0} {a}^{n - 1} + … + {D}_{j - 1} {a}^{n - j} + {D}_{j + 1} {a}^{n - j - 2} + … + {D}_{k - 1} {a}^{n - k} + \\ {D}_{k + 1} {a}^{n - k - 2} + … + {D}_{n - 1}\end{matrix}$$

$$\begin{matrix}{\tilde{S}}_{2} = {\sum }_{{i = 0}_{i \neq j , , i \neq k}}^{n - 1} {D}_{i} {a}^{2 ( n - i - 1 )} \\ = {D}_{0} {a}^{2 ( n - 1 )} + … + {D}_{j - 1} {a}^{2 ( n - j )} + {D}_{j + 1} {a}^{2 ( n - j - 2 )} + … + {D}_{k - 1} {a}^{2 ( n - k )} + \\ {D}_{k + 1} {a}^{2 ( n - k - 2 )} + … + {D}_{n - 1}\end{matrix}$$

Using the values of the stored reference checksums S₁, S₂ and the current checksums \tilde{S}₁, \tilde{S}₂, the computing unit calculates the value of the damaged areas of the information zones according to the formulas:

Dₖ=(S₂+\tilde{S}₂+(S₁+\tilde{S}₁)a^{n-j-1})[a^{2(n-k-1)}+a^{2(n-1)-j-k}]⁻¹

Dⱼ=S₁+\tilde{S}₁+Dₖa^{n-k-1})a^{-(n-j-1)}

The obtained values are recorded instead of the invalid.

Consider now the case, when three blocks of the stripe are damaged which corresponds to the failure of three disks array. In addition, this recovery method is applied, if unrecoverable reading error occurs (UER) during the reconstruction of two failed disks, and consequently, three blocks are damaged. If the blocks of the control zones are damaged, then the computing unit calculates the current checksum that corresponds to the damaged control zones using the checksum calculation formulas. The obtained checksum values are recorded instead of the damaged. If one or two of the three damaged blocks belongs to the information zone and the remained one belongs to the control zone, the data is restored according to the scheme described above for one or two of the failed blocks and the value of the damaged control zone is calculated according to the formula of checksums calculation.

blocks of the information zone be damaged, with their numbers j and k be discovered by the hardware

Let Dⱼ, Dₖ, Dₗ blocks of the information zone be damaged, with their numbers j, k and l be discovered by the hardware. Then, the current checksums \tilde{S}₀, \tilde{S}₁, \tilde{S}₂ are calculated using the computing unit with omitting the summands corresponding to the failed blocks:

$$\begin{matrix}{\tilde{S}}_{0} = {\sum }_{{i = 0}_{i \neq j , i \neq k , i \neq l}}^{n - 1} {D}_{i} \\ = {D}_{0} + {D}_{1} + … + {D}_{j - 1} + {D}_{j + 1} + … + {D}_{k - 1} + {D}_{k + 1} + … + {D}_{l - 1} + \\ {D}_{l + 1} + … + {D}_{n - 1}\end{matrix}$$

$$\begin{matrix}{\tilde{S}}_{1} = {\sum }_{{i = 0}_{i \neq j , i \neq k , i \neq l}}^{n - 1} {D}_{i} {a}^{n - i - 1} \\ = {D}_{0} {a}^{n - 1} + … + {D}_{j - 1} {a}^{n - j} + {D}_{j + 1} {a}^{n - j - 2} + … + {D}_{k - 1} {a}^{n - k} + \\ {D}_{k + 1} {a}^{n - k - 2} + … + {D}_{l - 1} {a}^{n - l} + {D}_{l + 1} {a}^{n - l - 2} + … + {D}_{n - 1}\end{matrix}$$

$$\begin{matrix}{\tilde{S}}_{2} = {\sum }_{{i = 0}_{i \neq j , i \neq k , i \neq l}}^{n - 1} {D}_{i} {a}^{2 ( n - i - 1 )} \\ = {D}_{0} {a}^{2 ( n - 1 )} + … + {D}_{j - 1} {a}^{2 ( n - j )} + {D}_{j + a} {a}^{2 ( n - j - 2 )} + … + {D}_{k - 1} {a}^{2 ( n - k )} + \\ {D}_{k + 1} {a}^{2 ( n - k - 2 )} + … + {D}_{l - 1} {a}^{2 ( n - l )} + {D}_{l + 1} {a}^{2 ( n - l - 2 )} + … + {D}_{n - 1}\end{matrix}$$

To restore the Dⱼ, Dₖ, Dₗ blocks the computing unit solves the following system:

$$( \begin{matrix}1 & 1 & 1 \\ {a}^{n - j - 1} & {a}^{n - k - 1} & {a}^{n - l - 1} \\ {a}^{2 ( n - j - 1 )} & {a}^{2 ( n - k - 1 )} & {a}^{2 ( n - l - 1 )}\end{matrix} ) ( \begin{matrix}{D}_{j} \\ {D}_{k} \\ {D}_{l}\end{matrix} ) = ( \begin{matrix}{S}_{0} + {\tilde{S}}_{0} \\ {S}_{1} + {\tilde{S}}_{1} \\ {S}_{2} + {\tilde{S}}_{2}\end{matrix} )$$

The matrix of this system is the Vandermonde matrix. Since its determinant

bⱼₖₗ=(a^{n-k-1}+a^{n-j-1})(a^{n-k-1}+a^{n-l-1})(a^{n-j-1}+a^{n-l-1})

is not equal to 0, the system of equations can be resolved uniquely.

Using the values of the stored reference checksums S₀, S₁, S₂ and the current checksums, \tilde{S}₀, \tilde{S}₁, \tilde{S}₂, the computing unit calculates the values of the damaged areas of information zones according to the formula:

Dₗ=[(S₀+\tilde{S}₀)(a^{n-j-1}a^{2(n-k-1)}+a^{n-k-1}a^{2(n-j-1)})+(S₁+\tilde{S}₁)(a^{2(n-k-1)}+a^{2(n-j-1)})+(S₂+\tilde{S}₂)(a^{n-k-1}+a^{n-j-1})]bⱼₖₗ⁻¹

Dₖ=(S₁+\tilde{S}₁+(S₀+\tilde{S}₀)a^{n-j-1}+Dₗ(a^{n-l-1}+a^{n-j-1}))(a^{n-k-1}+a^{n-j-1})⁻¹

Dⱼ=S₀+\tilde{S}₀+Dₖ+Dₗ

The obtained values are recorded instead of the invalid.

In the process of using the storage device, an analysis of the recorded data in the presence of corruption can be performed. The corruption of the data, instead of failure or damage of part of the storage device, is not registered by the hardware, and so, the fact of damage and its location is unknown. For an array of hard disks, the data corruption can be detected by stripes.

If the failed blocks do not exist in the stripe, then the corruption is defined by calculating the current checksum using a computing unit formula:

$${\tilde{S}}_{0} = {\sum }_{i = 0}^{n - 1} {D}_{i} = {D}_{0} + {D}_{1} + … + {D}_{n - 1}$$

$$\begin{matrix}{\tilde{S}}_{1} = {\sum }_{i = 0}^{n - 1} {D}_{i} {a}^{n - i - 1} \\ {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

The computing unit compares each of this values with the stored checksums S₀, S₁, S₂.

If S₀+\tilde{S}₀=0 and S₁+\tilde{S}₁=0 and S₂+\tilde{S}₂=0, i.e. the current checksums are equal to the reference checksums, the data corruption cannot be detected and the computing device starts to analysis the next stripe. If this condition is not satisfied, then the number of the block stripe with the corrupted data should be identified using the computational unit. The following conditions are verified with the aid of the computing unit:

If S₀+\tilde{S}₀≠0 and S₁+\tilde{S}₁=0 and S₂+\tilde{S}₂=0, then data corruption has been occurred in the block of the stripe corresponding to the checksum S₀.

If S₀+\tilde{S}₀=0 and S₁+\tilde{S}₁≠0 and S₂+\tilde{S}₂=0, then data corruption has been occurred in the block of the stripe corresponding to the checksum S₁.

If S₀+\tilde{S}₀=0 and S₁+\tilde{S}₁=0 and S₂+\tilde{S}₂≠0, then data corruption has been occurred in the block of the stripe corresponding to the checksum S₂.

If none of the above mentioned conditions are met, the conclusion should be deduced that the data corruption has been occurred in a block that corresponds to the information zone. In this case, the number (position) of this block is determined by using the computing unit according to the formula:

j=n−1−logₐ(S₁+\tilde{S}₁)(S₀+\tilde{S}₀)⁻¹

Here logₐ means the discrete logarithm to the base a of the element of the Galois field.

When the number of the damaged block is determined, the computing unit restores the value of this block, as it is described above for the case of the presence of a single failed block.

An analysis of the recorded data in the presence of corruption can be performed even if there was failure or damage of a part of the storage device. That is, prior to the recovery procedure for the failed or damaged parts of the storage device, the “healthy” data is analyzed for the presence of corruptions. The analyses of the presence of corruption and its correction is performed in order to ensure the correctness of the recovered data. The corrupted data, in contrast to the failure or damage of a part of the storage device, is not registered by the hardware, and so, the fact of damage and its location is unknown. For an array of hard disks, the data corruption can be detected by stripes.

If a failed stripe block is the block of the checksum S₂ then to analyze a corruption presence, the current checksums \tilde{S}₀, \tilde{S}₁ are calculated by using the computing unit by the formulas:

$${\tilde{S}}_{0} = {\sum }_{i = 0}^{n - 1} {D}_{i} = {D}_{0} + {D}_{1} + … + {D}_{n - 1}$$

$$\begin{matrix}{\tilde{S}}_{1} = {\sum }_{i = 0}^{n - 1} {D}_{i} {s}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

The computing block compares these value with the stored reference checksums S₀, S₁.

If (S₀+\tilde{S}₀=0 and S₁+\tilde{S}₁=0), i.e. the current checksums are equal to the reference checksums, so data corruption is not detected and the computing device proceeds to recover a failed block by calculating the checksum S₂. If this condition is not performed, the block number of the stripe with corrupted data is identified using the computational unit. To do this, use the computing unit to verify the following conditions:

If (S₀+\tilde{S}₀≠0 and S₁+\tilde{S}₁=0), then data corruption has occurred in the block of the stripe corresponding to the checksum S₀.

If (S₀+\tilde{S}₀=0 and S₁+\tilde{S}₁≠0), then data corruption has occurred in the block of the stripe corresponding to the checksum S₁.

If none of these conditions has been fulfilled, it can be concluded that data corruption has been occurred in a block corresponding to the information area. The number of this block is determined by using the computing unit according to the formula:

j=n−1−logₐ(S₁+\tilde{S}₁)(S₀+\tilde{S}₀)⁻¹

When the number of the damaged unit is defined, the computing unit restores the values of all the failed units, as is described above for the case of presence of two failed blocks of the stripe.

If the failed block of stripe is that one with checksum S₁, then to discover a corruption, the computing unit calculates the current checksum \tilde{S}₀, \tilde{S}₂ by the formulas:

$${\tilde{S}}_{0} = {\sum }_{i = 0}^{n - 1} {D}_{i} = {D}_{0} + {D}_{1} + … + {D}_{n - 1}$$

$$\begin{matrix}{\tilde{S}}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} \\ = ( ( ( {D}_{0} {a}^{2} + {D}_{1} ) {a}^{2} + {D}_{2} ) {a}^{2} + … + {D}_{n - 1} )\end{matrix}$$

The computing unit compares with each other the appropriate current checksums \tilde{S}₀, \tilde{S}₂ and the stored reference checksums S₀, S₂.

If (S₀+\tilde{S}₀=0 and S₂+\tilde{S}₂=0), i.e. the current checksum is equal to the reference checksum, so the data corruption is not detected and the computing device is transferred to the recovery of a failed unit, i.e. the checksum S₁. If this condition is not performed, then with the computational unit is the identification block of the stripe in which there was data corruption. To do this, using the computing unit checks the following conditions:

If (S₀+\tilde{S}₀≠0 and S₂+\tilde{S}₂=0), then data corruption has occurred in the block of the stripe corresponding to the checksum S₀.

If (S₀+\tilde{S}₀=0 and S₂+\tilde{S}₂≠0), then data corruption has occurred in the block of the stripe corresponding to the checksum S₁.

If not one of these conditions has been fulfilled, it means that data corruption has occurred in a block corresponding to the information zone, the number of this block is determined by using the computing unit according to the formula:

j=n−1−(logₐ(S₂+\tilde{S}₂)(S₀+\tilde{S}₀)⁻¹)/2

When the number of the damaged block is defined, a computing unit restores the values of all failed blocks, as described above for two failed blocks of the stripe.

If a checksum S₀ is the failed block of the stripe, then to analyze the presence of data corruption, the current checksums \tilde{S}₁, \tilde{S}₂ are calculated by using the formulas:

$$\begin{matrix}{\tilde{S}}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

$$\begin{matrix}{\tilde{S}}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} \\ = ( ( ( {D}_{0} {a}^{2} + {D}_{1} ) {a}^{2} + {D}_{2} ) {a}^{2} + … + {D}_{n - 1} )\end{matrix}$$

The computing unit compares with each other the appropriate current checksums \tilde{S}₁, \tilde{S}₂ and the stored reference checksums S₁, S₂.

If (S₁+\tilde{S}₁=0 and S₂+\tilde{S}₂=0), i.e. the current checksums are equal to the reference checksums, so data corruption is not detected and the computing device proceeds to recover a failed block, that is, to calculate the checksum S₀. If this condition is not performed, then number of the block stripe with the corrupted data is identified using the computational unit.

The following conditions are verified with the aid of the computing unit:

If (S₁+\tilde{S}₁≠0 and S₂+\tilde{S}₂=0), then data corruption has occurred in the block of the stripe corresponding to the checksum S₁.

If (S₁+\tilde{S}₁=0 and S₂+\tilde{S}₂≠0), then data corruption has occurred in the block of the stripe corresponding to the checksum S₂. If not one of these conditions is met, it means that data corruption has occurred in a block corresponding to the information zone, the number of this block is determined by using the computing unit according to the formula:

j=n−1−logₐ(S₁+\tilde{S}₁)(S₀+\tilde{S}₀)⁻¹

When the number of the damaged block is defined, the computing unit restores the value of these blocks, as it is described above for one of the failed blocks of the stripe.

If the failed block stripe is the block, which corresponds to Dⱼ information zone, where j is the number of the damaged block in the stripe, it is known to us, because the failure is logged by the hardware. Then, the computing unit calculates the current checksums \tilde{S}₀, \tilde{S}₁, \tilde{S}₂ to discover the data corruption by the formulas:

$${\tilde{S}}_{0} = {\sum }_{i = 0}^{n - 1} {D}_{i} = {D}_{0} + {D}_{1} + … + {D}_{n - 1}$$

$$\begin{matrix}{\tilde{S}}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$

$$\begin{matrix}{\tilde{S}}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} \\ = ( ( ( {D}_{0} {a}^{2} + {D}_{1} ) {a}^{2} + {D}_{2} ) {a}^{2} + … + {D}_{n - 1} )\end{matrix}$$

We introduce an auxiliary notation:

U₁=(S₀+\tilde{S}₀)a^{n-j-1}+S₁+\tilde{S}₁

U₂=(S₀+\tilde{S}₀)a^{2(n-j-1)}+S₂+\tilde{S}₂

U₃=(S₁+\tilde{S}₁)a^{n-j-1}+S₂+\tilde{S}₂

The computing unit verifies the following conditions to define a data corruption:

If (U₁=0 and U₂=0), a corrupted data is not detected, and the failed block can be recovered, as it is described above for one of the failed block stripe. If this condition is not performed, then the number of the blocks stripe is identified with the corrupted data using the computational unit. To do this, by using the computing unit the following conditions are verified:

If (U₁≠0 and U₂≠0 and U₃=0), then data corruption has occurred in the block of the stripe, which corresponds to the checksum S₀.

If (U₁≠0 and U₂=0 and U₃≠0), then data corruption has occurred in the block of the stripe, which corresponds to the checksum S₁.

If (U₁=0 and U₂≠0 and U₃≠0), then data corruption has occurred in the block stripe, which corresponds to the checksum S₂.

If not one of these conditions is met, it means that the data corruption has occurred in a block that corresponds to the information zone, the number of this block is determined by using the computing unit according to the formula:

k=n−1−logₐ(S₂+\tilde{S}₂+(S₁+\tilde{S}₁)a^{n-j-1})(S₁+\tilde{S}₁+(S₀+\tilde{S}₀)a^{n-j-1})⁻¹

When the number of the damaged block is defined, the computing unit restores the values of all failed blocks, as it is described above for two failed blocks of the stripe.

It may be observed, that the computing unit may be included in the storage device, i.e. to be a part of it, but it can be an external tool regarding this storage device, for example, when the process of work of a memory device is organized with several independent devices. Thus, in this case the external device can be a network server, managing the work of several databases, united by a served network.

Another object of the present invention is a system containing the said storage device and a computing unit providing the said operation.

### INDUSTRIAL APPLICABILITY

The method and the system to recover records in the storage device solve the problem of data storage reliability according to modern and prospective storage devices. This invention allows systems of more than 24 TB, while recovering several simultaneously failed parts of a storage device and providing the ability to recover data not only in case of failure, but also in case of corruption.

What is claimed is:

1. A method of recovery of records in a storage device in case of failure or damage of a part of the storage device or data corruption of the storage device, the method comprising:
dividing an area of memory of the storage device into information zones of a same size selected from different parts of the storage device, and into control zones selected from different parts of the storage device;
recording each group of data to be stored in a form of a set of code words into the corresponding information zone;
finding three reference checksums S₀, S₁, S₂ using a corresponding computing unit while writing the data into the storage device, every checksum being calculated by a corresponding predetermined formula:
$${\tilde{S}}_{0} = {\sum }_{i = 0}^{n - 1} {D}_{i} = {D}_{0} + {D}_{1} + … + {D}_{n - 1}$$
$$\begin{matrix}{\tilde{S}}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$
$$\begin{matrix}{\tilde{S}}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} \\ = ( ( ( {D}_{0} {a}^{2} + {D}_{1} ) {a}^{2} + {D}_{2} ) {a}^{2} + … + {D}_{n - 1} )\end{matrix}$$
where Dᵢ is an i-information area wherein code words d_{i,1}, d_{i,2}, . . . , d_{i,s-1}; i=0, . . . , n−1 are recorded, the code words being elements of the Galois field;
n is a number of the information zones;
s is a number of the code words in one information zone;
a is a primitive element of the Galois field;
writing each of the reference checksum in the form of the code words with the same number in the corresponding control zone, wherein each of the three checksums is stored in a separate zone of the storage device;
using the computing unit to calculate the current checksums by the predetermined formula for each set of code words with the same numbers in all information zones while using the storage device in case of failure or damage of a part of the storage device or data corruption; and
using the reference and the current checksum to perform data recovery by solving systems of equations obtained from the formulas of calculating checksums, the number of equations in the system being dependent on the number of failed or damaged areas of the storage device.

2. The method according to claim 1, further comprising using the values of the stored reference checksums and the current checksums to detect the data corruption.

3. The method according to claim 1, comprising, prior to the data recovery, comparing the reference and the current checksums to determine the presence of the data corruption and its location by using the system of equations obtained from calculating the formulas of checksums.

4. The method according to claim 1, wherein the computing unit is included in the said storage device.

5. The method according to claim 1, wherein the computing unit is external to the storage device.

6. A system of recovery of records in a storage device in case of failure or damage of a part of the storage device or data corruption of the storage device, the system comprising:
a memory device comprising n equal size information zones selected from different parts of the storage device and three control zones selected from different parts of the storage device, each of the n information zones of the storage device being adapted to write groups of data to be recorded as a set of code words, and each of the three control zones of the storage device being adapted to record a corresponding checksum; and
a computing unit defining current checksums by formulas for each set of code words with the same numbers in all said n information zones in case of failure or damage of a part of memory of the storage device, values of stored reference checksums serving to recover lost data;
wherein the computing unit defines reference checksums by using a predetermined formula, for each set of code words, where i=0, . . . , n−1 in all said n information zones with every record of data in the storage device, and wherein S₀, S₁, S₂ checksums are calculated according to the following formulas:
$${\tilde{S}}_{0} = {\sum }_{i = 0}^{n - 1} {D}_{i} = {D}_{0} + {D}_{1} + … + {D}_{n - 1}$$
$$\begin{matrix}{\tilde{S}}_{1} = {\sum }_{i = 0}^{n - 1} {D}_{i} {a}^{n - i - 1} \\ = {D}_{0} {a}^{n - 1} + {D}_{1} {a}^{n - 2} + … + {D}_{n - 1} \\ = ( ( ( {D}_{0} a + {D}_{1} ) a + {D}_{2} ) a + … + {D}_{n - 1} )\end{matrix}$$
$$\begin{matrix}{\tilde{S}}_{2} = {\sum }_{i = 0}^{n - 1} {D}_{i} {a}^{2 ( n - i - 1 )} \\ = {D}_{0} {a}^{2 ( n - 1 )} + {D}_{1} {a}^{2 ( n - 2 )} + … + {D}_{n - 1} \\ = ( ( ( {D}_{0} {a}^{2} + {D}_{1} ) {a}^{2} + {D}_{2} ) {a}^{2} + … + {D}_{n - 1} )\end{matrix}$$
where Dᵢ is an i-information area wherein code words d_{i,1}, d_{i,2}, . . . , d_{i,s-1}; i=0, . . . , n−1 are recorded, the code words being elements of the Galois field;
n is a number of the information zones;
s is a number of the code words in one information zone;
a is a primitive element of the Galois field;
and wherein the lost data can be recovered using the reference and the current checksums by solving a system of equations obtained by the formula for calculating the checksums, the number of equations in the system depending on the number of failed or damaged areas of the storage device.

7. The system according to claim 6, wherein the computing unit is configured to use the values of the stored reference checksums and the current checksums to detect data corruption.

8. The system according to claim 6, wherein in prior to recovering the data, the reference and the current checksums are compared to determine a presence of data corruption and its location by using the system of equations obtained from calculating the formulas of checksums.

9. The system according to claim 6, wherein the computing unit is included in the storage device.

10. The system according to claim 6, wherein the computing unit is external to the storage device.
